(19) United States
(12) Patent Application Publication
(10) Pub. No.: US 2022/0131335 A1
(43) Pub. Date: Apr. 28, 2022

(54) LASER APPARATUS, LASER PROCESSING SYSTEM, AND METHOD FOR MANUFACTURING ELECTRONIC DEVICE

(71) Applicant: Gigaphoton Inc., Tochigi (JP)

(72) Inventors: Akiyoshi SUZUKI, Oyama-shi (JP); Hironori IGARASHI, Oyama-shi (JP)

(73) Assignee: Gigaphoton Inc., Tochigi (JP)

(21) Appl. No.: 17/569,380

(22) Filed: Jan. 5, 2022

Related U.S. Application Data
(63) Continuation of application No. PCT/JP2019/034236, filed on Aug. 30, 2019.

(51) Int. Cl. H01S 3/10; H01S 3/225; H01S 5/40; H01S 5/00; H01S 3/23; H01S 5/12; G02F 1/35; H01S 3/16; H01S 3/067; B23K 26/06

(52) U.S. Cl. CPC H01S 3/10092; B23K 26/0643; H01S 5/4025; H01S 5/0092; H01S 3/2366; H01S 5/12; G02F 1/354; H01S 3/1625; H01S 3/1636; H01S 3/06754; G02F 1/3507; H01S 3/06716; H01S 3/1618; H01S 3/1608; H01S 3/2251

(57) ABSTRACT

A laser apparatus according to an aspect of the present disclosure includes a plurality of semiconductor lasers, a plurality of optical switches disposed in the optical paths of the plurality of respective semiconductor lasers, a wavelength conversion system configured to convert pulsed beams outputted from the plurality of optical switches in terms of wavelength to generate wavelength-converted beams, an ArF excimer laser amplifier configured to amplify the wavelength-converted beams, and a controller configured to control the operations of the plurality of semiconductor lasers and the plurality of optical switches, and the plurality of semiconductor lasers are each configured to output a laser beam so produced that wavelengths of the wavelength-converted beams are wavelengths at which the ArF excimer laser amplifier performs amplification and differ from the optical absorption lines of oxygen.

### CROSS-REFERENCE TO RELATED APPLICATIONS

The present application is a continuation application of International Application No. PCT/JP2019/034236, filed on Aug. 30, 2019, the entire contents of which are hereby incorporated by reference.

### BACKGROUND

### 1. Technical Field

The present disclosure relates to a laser apparatus, a laser processing system, and a method for manufacturing an electronic device.

### 2. Related Art

In recent years, a semiconductor exposure apparatus is required to improve the resolution thereof as semiconductor integrated circuits are increasingly miniaturized and highly integrated. To this end, reduction in the wavelength of the light outputted from a light source for exposure is underway. For example, a KrF excimer laser apparatus, which outputs a laser beam having a wavelength of about 248 nm, and an ArF excimer laser apparatus, which outputs a laser beam having a wavelength of about 193 nm, are used as a gas laser apparatus for exposure.

The beam from spontaneously oscillating KrF and ArF excimer laser apparatuses has a wide spectral linewidth ranging from 350 to 400 pm. A projection lens made of a material that transmits ultraviolet light, such as KrF and ArF laser beams, therefore produces chromatic aberrations in some cases. As a result, the resolution of the projection lens may decrease. To avoid the decrease in the resolution, the spectral linewidth of the laser beam outputted from the gas laser apparatus needs to be narrow enough to make the chromatic aberrations negligible. To this end, a line narrowing module (LNM) including a line narrowing element (such as etalon and grating) is provided in a laser resonator of the gas laser apparatus to narrow the spectral linewidth in some cases. A gas laser apparatus providing a narrowed spectral linewidth is hereinafter referred to as a narrowed-line gas laser apparatus.

### CITATION LIST

### Patent Literature

[PTL 1] US Patent Application Publication No. 2010/0220756
[PTL 2] JP-A-2003-163393
[PTL 3] WO 2018/100638

### SUMMARY

A laser apparatus according to an aspect of the present disclosure includes a plurality of semiconductor lasers, a plurality of optical switches disposed in optical paths of the plurality of respective semiconductor lasers, a wavelength conversion system configured to convert pulsed beams outputted from the plurality of optical switches in terms of wavelength to generate wavelength-converted beams, an ArF excimer laser amplifier configured to amplify the wavelength-converted beams outputted from the wavelength conversion system, and a controller configured to control operations of the plurality of semiconductor lasers and the plurality of optical switches. The plurality of semiconductor lasers are each configured to output a laser beam so produced that wavelengths of the wavelength-converted beams outputted from the wavelength conversion system are wavelengths at which the ArF excimer laser amplifier performs amplification. The laser beams outputted from the plurality of semiconductor lasers have wavelengths different from each other. The plurality of semiconductor lasers are configured to output the laser beams so produced that the wavelengths of the wavelength-converted beams differ from an optical absorption line of oxygen.

A method for manufacturing an electronic device according to another aspect of the present disclosure uses a plurality of semiconductor lasers, a plurality of optical switches disposed in optical paths of the plurality of respective semiconductor lasers, a wavelength conversion system configured to convert pulsed beams outputted from the plurality of optical switches in terms of wavelength to generate wavelength-converted beams, an ArF excimer laser amplifier configured to amplify the wavelength-converted beams outputted from the wavelength conversion system, and a controller configured to control operations of the plurality of semiconductor lasers and the plurality of optical switches. The plurality of semiconductor lasers are each configured to output a laser beam so produced that wavelengths of the wavelength-converted beams outputted from the wavelength conversion system are wavelengths at which the ArF excimer laser amplifier performs amplification. The laser beams outputted from the plurality of semiconductor lasers have wavelengths different from each other. The plurality of semiconductor lasers are configured to generate excimer laser beams by using laser apparatuses configured to output the laser beams so produced that the wavelengths of the wavelength-converted beams generated by the wavelength conversion differ from an optical absorption line of oxygen. The method includes outputting an excimer laser beam to a processing apparatus and irradiating a radiation receiving object with the excimer laser beam in the processing apparatus to manufacture an electronic device.

### BRIEF DESCRIPTION OF THE DRAWINGS

Embodiments of the present disclosure will be described below only by way of example with reference to the accompanying drawings.

FIG. 1 schematically shows the configuration of a laser processing system according to Comparative Example.

FIG. 2 is a graph showing the spectral waveform of an ArF excimer laser beam produced in self oscillation (free running).

FIG. 3 schematically shows the configuration of a laser apparatus according to a first embodiment.

FIG. 4 is a graph showing an example of the spectrum of a multiline pulsed laser beam outputted from a wavelength conversion system.

FIG. 5 is a timing chart showing an example of the operation of a plurality of optical switches.

FIG. 6 schematically shows the configuration of a laser apparatus according to a second embodiment.

FIG. 7 is a graph showing an example of the spectrum of a multiline pulsed laser beam outputted from a wavelength-tunable multiline solid-state laser system.

FIG. 8 schematically shows the operation of a plurality of wavelength conversion systems.

FIG. 9 schematically shows an example of the configuration of a wavelength-tunable multiline solid-state laser system using a titanium-sapphire amplifier.

FIG. 10 schematically shows an example of the configuration of a wavelength-tunable multiline solid-state laser system using a second harmonic generator.

FIG. 11 schematically shows an example of the configuration of a wavelength-tunable multiline solid-state laser system using two types of fiber lasers.

FIG. 12 schematically shows another example of the configuration of the wavelength-tunable multiline solid-state laser system using two types of fiber lasers.

### DETAILED DESCRIPTION

<Contents>

1. Description of laser processing system according to Comparative Example

### 1.1 Configuration

### 1.2 Operation

1.2.1 Operation of laser apparatus
1.2.2 Operation of processing apparatus
1.2.2.1 Operation of preparing laser radiation
1.2.2.2 Operation during laser radiation
1.3 Description of spectral waveform

### 1.4 Problems

### 2. First Embodiment

### 2.1 Configuration

### 2.2 Operation

2.3 Effects and advantages

### 3. Second Embodiment

### 3.1 Configuration

### 3.2 Operation

3.3 Effects and advantages

### 3.4 Variations

4. Variations of wavelength-tunable multiline solid-state laser system
4.1 Example using titanium-sapphire amplifier

### 4.1.1 Configuration

### 4.1.2 Advantages

4.2 Example using second harmonic generator in wavelength conversion system

### 4.2.1 Configuration

### 4.2.2 Advantages

4.3 Example 1 using two types of fiber lasers

### 4.3.1 Configuration

### 4.3.2 Operation

### 4.3.3 Variations

4.4 Example 2 using two types of fiber lasers

### 4.4.1 Configuration

### 4.4.2 Operation

### 4.4.3 Variations

5. Method for manufacturing electronic device

### 6. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same component has the same reference character, and no redundant description of the same component will be made.

### 1. Description of Laser Processing System According to Comparative Example

### 1.1 Configuration

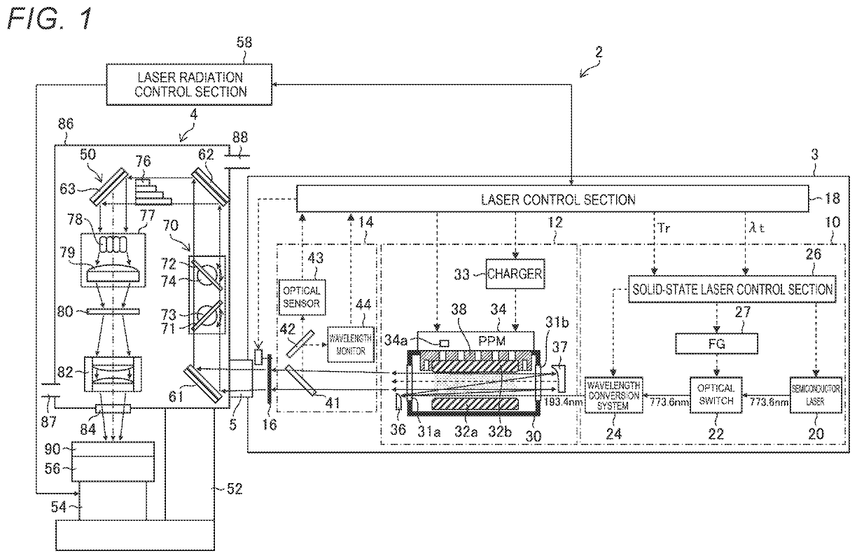

FIG. 1 schematically shows the configuration of a laser processing system 2 according to Comparative Example. The laser processing system 2 includes a laser apparatus 3 and a processing apparatus 4. The laser apparatus 3 is a wavelength-tunable ArF excimer laser apparatus and includes a wavelength-tunable solid-state laser system 10, an amplifier 12, a monitor module 14, a shutter 16, and a laser control section 18.

The wavelength-tunable solid-state laser system 10 includes a semiconductor laser 20, an optical switch 22, a wavelength conversion system 24, a solid-state laser control section 26, and a function generator (FG) 27.

The semiconductor laser 20 is a seed laser that operates in a single longitudinal mode and outputs a laser beam having a wavelength of about 773.6 nm as a seed beam based on continuous wave (CW) oscillation. The semiconductor laser 20 is, for example, a distributed feedback semiconductor laser, and the oscillation wavelength at which the semiconductor laser oscillates can be changed by changing the semiconductor temperature setting. The semiconductor laser 20 outputs a beam having a wavelength changeable around 773.6 nm.

The optical switch 22 is disposed in the optical path of the seed beam outputted from the semiconductor laser 20. The optical switch 22 converts the seed beam into pulses at the timings specified by the solid-state laser control section 26 and outputs the pulses in the form of a pulsed beam. The optical switch 22 generates the pulsed beam by controlling the beam passage timings and amplifying the beam. The optical switch 22 may be formed of the combination of a device that controls the beam passage timings and a device that amplifies the beam or may be formed of a single device having both the functions. The optical switch 22 may, for example, be a semiconductor optical amplifier (SOA).

The wavelength conversion system 24 is a wavelength conversion system that uses a nonlinear crystal to generate a fourth harmonic and includes, for example, an LBO crystal and a KBBF crystal that are not shown. The term “LBO” corresponds to the chemical formula LiB₃O₅. The term “KBBF” corresponds to the chemical formula KBe₂BO₃F₂.

The LBO and KBBF crystals are disposed on respective rotating stages that are not shown in the figures, whereby the angle of incidence of the laser beam incident on each of the crystals can be changed.

The amplifier 12 is an ArF excimer laser amplifier. The amplifier 12 includes a laser chamber 30, a charger 33, a pulse power module (PPM) 34, a convex mirror 36, and a concave mirror 37.

The laser chamber 30 is a chamber that encapsulates an ArF laser gas and includes windows 31a and 31b and a pair of electrodes 32a and 32b. The electrodes 32a and 32b are disposed in the laser chamber 30 as electrodes that produce discharge to excite the laser medium.

The laser chamber 30 has an opening, and an insulator 38 closes the opening. The electrode 32b is supported by the insulator 38, and the electrode 32a is supported by a return plate that is not shown. The return plate is connected to the inner surface of the laser chamber 30 via wiring that is not shown. Electrical conductors are buried in the insulator 38. The electrical conductors apply a high voltage supplied from the pulse power module 34 to the electrode 32b.

The charger 33 is a DC power supply that supplies a predetermined voltage to charge a charging capacitor that is not shown but is provided in the pulse power module 34. The pulse power module 34 includes a switch 34a controlled by the laser control section 18. When the switch 34a is changed from the turned-off state to the turned-on state, the pulse power module 34 generates a pulsed high voltage from the electric energy held in the charger 33 and applies the high voltage to the space between the pair of electrodes 32a and 32b.

When the high voltage is applied to the space between the pair of electrodes 32a and 32b, the insulation between the pair of electrodes 32a and 32b is broken down and discharge occurs. The energy of the discharge excites the laser medium in the laser chamber 30, and the excited laser medium transitions to a high energy level. Thereafter, when the excited laser medium transitions to a low energy level, the laser medium emits light according to the difference between the energy levels.

The windows 31a and 31b are disposed at opposite ends of the laser chamber 30. The light generated in the laser chamber 30 exits out of the laser chamber 30 via the windows 31a and 31b.

The convex mirror 36 and the concave mirror 37 are so disposed that the pulsed laser beam outputted from the wavelength-tunable solid-state laser system 10 passes through the laser chamber 30 three times (three passes) so that the beam enlarges.

The monitor module 14 is disposed in the optical path of the pulsed laser beam outputted from the amplifier 12. The monitor module 14 includes a first beam splitter 41, a second beam splitter 42, an optical sensor 43, and a wavelength monitor 44.

The first beam splitter 41 transmits at high transmittance the pulsed laser beam outputted from the amplifier 12 toward the shutter 16 and reflects part of the pulsed laser beam toward the second beam splitter 42. The second beam splitter 42 transmits part of the pulsed laser beam reflected off the first beam splitter 41 toward the light receiving surface of the optical sensor 43 and reflects the other part toward the light receiving surface of the wavelength monitor 44. The optical sensor 43 detects the pulse energy of the pulsed laser beam incident on the light receiving surface and outputs data on the detected pulse energy to the laser control section 18. The wavelength monitor 44 measures the wavelength of the pulsed laser beam incident on the light receiving surface and outputs data on the measured wavelength to the laser control section 18.

The shutter 16 is disposed in the optical path of the pulsed laser beam having passed through the first beam splitter 41. The opening and closing operation of the shutter 16 is controlled by the laser control section 18.

The optical path from the semiconductor laser 20 to the exit at the shutter 16 is sealed by an enclosure and an optical path tube, both of which are not shown, and is purged with a nitrogen gas. The laser apparatus 3 and the processing apparatus 4 are connected to each other via an optical path tube 5. The nitrogen gas also flows through the optical path tube 5, and the optical path tube 5 is sealed with an O-ring at the portion where the optical path tube 5 is connected to the processing apparatus 4 and with another O-ring at the portion where the optical path tube 5 is connected to the laser apparatus 3.

The processing apparatus 4 includes a radiation optical system 50, a frame 52, an XYZ stage 54, a table 56, and a laser radiation control section 58.

The radiation optical system 50 includes high-reflectance mirrors 61, 62, and 63, an attenuator 70, an optical path difference prism 76, a beam homogenizer 77, a mask 80, a transfer optical system 82, a window 84, and a housing 86.

The high-reflectance mirror 61 is so disposed that the pulsed laser beam having passed through the optical path tube 5 passes through the attenuator 70 and is incident on the high-reflectance mirror 62.

The attenuator 70 is disposed in the optical path between the high-reflectance mirrors 61 and 62 and includes two partial reflection mirrors 71 and 72 and rotary stages 73 and 74, which change the angles of incidence of the pulsed laser beam incident on the mirrors 71 and 72.

The high-reflectance mirror 62 is so disposed that the pulsed laser beam having passed through the attenuator 70 passes through the optical path difference prism 76.

The optical path difference prism 76 is a coherence lowering optical system. The optical path difference prism 76 is disposed in the optical path between the attenuator 70 and the beam homogenizer 77. The length of one rod of the optical path difference prism 76 is determined by the coherence length of the laser beam that enters the optical path difference prism 76. For example, when the spectral linewidth of the incident laser beam is 0.3 pm, the coherence length is about 12.5 cm. The material of the optical path difference prism 76 is, for example, CaF₂ and the refractive index of CaF₂ at the wavelength of 193 nm is about 1.5, so that the length of one rod of the optical path difference prism 76 is about 25 cm.

The beam homogenizer 77 and the mask 80 are disposed in the optical path between the optical path difference prism 76 and the transfer optical system 82. The beam homogenizer 77 includes a fly-eye lens 78 and a condenser lens 79 and is so disposed that the mask 80 is illuminated in Koehler illumination.

The mask 80 is a photomask that defines an exposure pattern applied to a radiation receiving object 90. The exposure pattern may also be called a processing pattern or a radiation pattern.

The transfer optical system 82 is so disposed as to form an image of the mask 80 on the surface of the radiation receiving object 90 via the window 84.

The transfer optical system 82 may be a combination lens formed of a plurality of lenses, which may form a reduction projection optical system. The window 84 is disposed in the optical path between the transfer optical system 82 and the radiation receiving object 90 and is fixed to an opening of the housing 86 with the space between the window 84 and the opening sealed with an O-ring that is not shown.

The window 84 is a substrate made of CaF₂ crystal or synthetic quartz, which transmits the excimer laser beam, and coated with reflection suppression films on opposite sides.

The housing 86 has an intake port 87, via which the nitrogen gas is introduced into the housing 86, and an exhaust port 88, via which the nitrogen gas is discharged out of the housing 86. The intake port 87 can be connected to a gas supply tube that is not shown, and the exhaust port 88 can be connected to a gas discharge tube that is not shown. The intake port 87 and the exhaust port 88 are so sealed with O-rings that are not shown that the interior of the housing 86 is not contaminated with the outside air in the state in which the gas supply tube and the gas discharge tube are connected to the respective ports. A nitrogen gas supply source that is not shown is connected to the intake port 87. The nitrogen gas supply source includes, for example, a nitrogen gas cylinder.

The radiation optical system 50 and the XYZ stage 54 are fixed to the frame 52. The XYZ stage 54 is a motorized stage movable along three axes perpendicular to one another, an axis-X direction, an axis-Y direction, and an axis-Z direction. The table 56 is disposed on the XYZ stage 54, and the radiation receiving object 90 is placed on the table 56. The radiation receiving object 90 is also called a workpiece. The radiation receiving object 90 does not necessarily have a specific form. The radiation receiving object 90 may, for example, be a semiconductor material or an impurity source film formed on a semiconductor material and containing an impurity element. The material of the radiation receiving object 90 may, for example, be a glass material, a ceramic material, or a polymer material.

A controller that functions as the laser control section 18, the solid-state laser control section 26, the laser radiation control section 58, and other control sections can be achieved by the combination of hardware formed of one or more computers and software installed thereon. The software is also called a program. A programmable controller is encompassed in the concept of a computer. The computer can be formed of a CPU (central processing unit) and a memory. The CPU provided in the computer is an example of a processor.

Part or entirety of the processing functions of the controller may be achieved by using an integrated circuit represented by an FPGA (field programmable gate array) and an ASIC (application specific integrated circuit).

The functions of a plurality of controllers can be achieved by a single controller. Further, in the present disclosure, the controllers may be connected to each other via a communication networks, such as a local area network and the Internet. In a distributed computing environment, a program unit may be saved both in local and remote memory storage devices.

1.2 Operation

### 1.2.1 Operation of Laser Apparatus

The operation of the laser apparatus 3 will be described. The laser control section 18 transmits and receives a variety of signals to and from the laser radiation control section 58. For example, the laser control section 18 receives a target wavelength λt, target pulse energy Et, and other pieces of data and a light emission trigger signal Tr from the laser radiation control section 58. Upon receipt of the data on the target wavelength λt and the target pulse energy Et from the laser radiation control section 58, the laser control section 18 transmits the data on the target wavelength λt to the solid-state laser control section 26 and sets the charging voltage in the charger 33 in such a way that the target pulse energy Et is achieved.

When the data on the target wavelength λt is inputted from the laser control section 18 to the solid-state laser control section 26, the solid-state laser control section 26 changes an oscillation wavelength λ1 at which the semiconductor laser 20 oscillates in such a way that the laser beam outputted from the wavelength conversion system 24 has the wavelength λt. In the description, the oscillation wavelength λ1 is four times longer than the target wavelength λt. That is, the following relationship is satisfied.

λ1=4λt

The solid-state laser control section 26 controls the two rotary stages, which are not shown in the figures, in such a way that the laser beam is incident on the rotary stages at angles of incidence that maximize the wavelength conversion efficiency of the LBO and KBBF crystals in the wavelength conversion system 24.

When the light emission trigger signal Tr is inputted to the solid-state laser control section 26 from the laser control section 18, the solid-state laser control section 26 transmits a signal to the optical switch 22 via the function generator 27. As a result, the wavelength conversion system 24 outputs a pulsed laser beam having the target wavelength λt.

When the laser control section 18 receives the light emission trigger signal Tr from the laser radiation control section 58, the laser control section 18 transmits a trigger signal to each of the switch 34a of the pulse power module 34 and the optical switch 22, so that the discharge occurs when the pulsed laser beam outputted from the wavelength-tunable solid-state laser system 10 enters the discharge space in the laser chamber 30 of the amplifier 12.

As a result, the pulsed laser beam outputted from the wavelength-tunable solid-state laser system 10 undergoes three-pass amplification performed by the amplifier 12. The pulsed laser beam amplified by the amplifier 12 is sampled by the first beam splitter 41 of the monitor module 14, and the optical sensor 43 and the wavelength monitor 44 measure pulse energy E and a wavelength λ, respectively.

The laser control section 18 controls the charging voltage applied to the charger 33 in such a way that a difference between the pulse energy E measured by the monitor module 14 and the target pulse energy Et approaches zero. The laser control section 18 further controls the oscillation wavelength λ1, at which the semiconductor laser 20 oscillates, in such a way that a difference between the wavelength λ measured by the monitor module 14 and the target wavelength λt approaches zero.

The pulsed laser beam having passed through the first beam splitter 41 enters the processing apparatus 4 via the shutter 16.

1.2.2 Operation of Processing Apparatus

### 1.2.2.1 Operation of Preparing Laser Radiation

The operation of preparing the laser radiation in the processing apparatus 4 will be described.

Prior to the laser radiation to the radiation receiving object 90, the laser radiation control section 58 controls the XYZ stage 54 in such a way that a predetermined irradiation region of the radiation receiving object 90 is irradiated with the laser beam at a predetermined height.

The laser radiation control section 58 causes the rotary stages 73 and 74 to control the angles of incidence of the laser beam incident on the two partial reflection mirrors 71 and 72 of the attenuator 70 in such a way that the fluence at the position of the surface of the radiation receiving object 90 (that is, the position of the image of the mask 80) is a target fluence F.

The preparation for the laser radiation is thus completed.

1.2.2.2 Operation During Laser Radiation

The operation during the laser radiation in the processing apparatus 4 will be described. After completing the preparation for the laser radiation, the laser radiation control section 58 transmits one light emission trigger signal Tr to the laser control section 18. The pulsed laser beam having passed through the first beam splitter 41 of the monitor module 14 enters the processing apparatus 4 through the optical path tube 5 in synchronization with the light emission trigger signal Tr.

The pulsed laser beam is reflected off the high-reflectance mirror 61 and passes through the attenuator 70. After passing through the attenuator 70, the attenuated pulsed laser beam is reflected off the high-reflectance mirror 62 and passes through the optical path difference prism 76.

The optical path difference prism 76 causes the pulsed laser beam to have an optical path difference according to the position where the pulsed laser beam passes therethrough. The temporal coherence of the pulsed laser beam decreases when the pulsed laser beam passes through the optical path difference prism 76.

The pulsed laser beam having passed through the optical path difference prism 76 is spatially homogenized in terms of optical intensity by the beam homogenizer 77 and is incident on the mask 80. It is preferable that the shape of the beam with which the mask 80 is uniformly illuminated is larger than holes (light passage areas) in the mask 80, and that the mask 80 is illuminated with the beam having a shape that substantially coincides with the shape of the mask.

The pulsed laser beam having passed through the mask 80 enters the transfer optical system 82, which transfers the pulsed laser beam onto the surface of the radiation receiving object 90 and brings the pulsed laser beam into focus thereon. For example, when an impurity source film containing an impurity element and formed on the surface of a semiconductor material is used as the radiation receiving object 90, the pulsed laser beam having passed through the mask 80 is transferred onto and brought into focus on the surface of the impurity source film containing an impurity element, resulting in ablation of the impurity source film containing an impurity element, so that the semiconductor material is doped with the impurity.

When the laser radiation to the irradiation region, which is the initial processing position, is completed, the laser radiation control section 58 sets data on the next processing position, if any, in the XYZ stage 54. The laser radiation control section 58 controls the XYZ stage 54 to move the radiation receiving object 90 to the next processing position, and the radiation receiving object 90 is irradiated with the laser beam in the next processing position.

When there is no next processing position, the laser radiation control section 58 terminates the laser radiation. The procedure described above is repeated until the irradiation regions in all processing positions on the radiation receiving object 90 are irradiated with the laser beam.

As described above, the radiation of the pulsed laser beam may be performed in accordance with a “step-and-repeat scheme”, in which the pulsed laser beam is radiated for each radiation area that is part of the radiation receiving object 90.

1.3 Description of Spectral Waveform

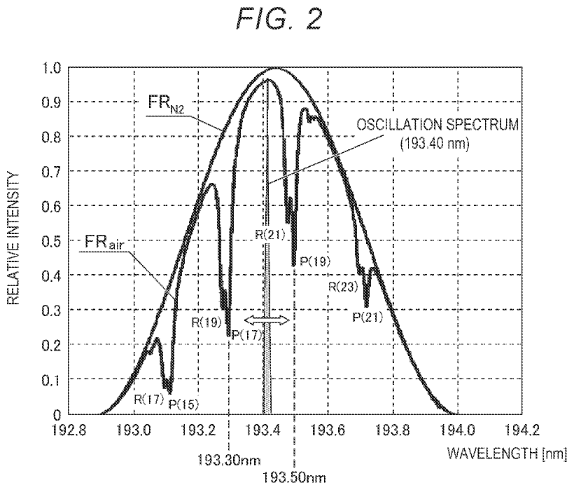

FIG. 2 shows the spectral waveform of the ArF excimer laser beam produced in self oscillation (free running) with no line narrowing. A spectral waveform FR_{N2} in the nitrogen gas has a central wavelength of about 193.4 nm and a spectral linewidth of about 450 pm as the full width at half maximum (FWHM). It is known that oxygen has a plurality of absorption lines, which are absorption bands where a laser beam is absorbed. The “absorption lines” each correspond to a wavelength at which oxygen absorbs light and also correspond to a wavelength band expressed by a peak curve along which the absorption coefficient abruptly increases in a graph of the optical absorption spectrum showing the absorption characteristics of oxygen.

Since the wavelength range where the ArF excimer laser beam is self oscillated overlaps with the plurality of absorption lines of oxygen, oxygen absorbs the laser beam in a gas containing oxygen, for example, in the air. An in-air spectral waveform FRₐᵢᵣ therefore shows drops in optical intensity I at a plurality of absorption lines, as compared with the spectral waveform FR_{N2} in the nitrogen gas containing no oxygen, as shown in FIG. 2. The relative intensity along the vertical axis of FIG. 2 is the normalized optical intensity I.

The plurality of absorption lines result from absorption transition of the Schumann-Runge band of oxygen, have a vibrational band in the vicinity of 193 nm, and have absorption characteristics indicated by branches R(17), P(15), R(19), P(17), R(21), P(19), P(23), and P(21) for each rotational level, as shown in FIG. 2. In the spectral waveform FRₐᵢᵣ of the ArF excimer laser beam, the optical intensity I drops at the absorption lines corresponding to the branches, as shown in FIG. 2.

On the other hand, oxygen hardly absorbs the laser beam in the inter-absorption-line regions, which are wavelength bands where the laser beam is less absorbed than at the absorption lines. An inter-absorption-line wavelength band that does not overlap with any of the absorption lines is referred to as a “non-absorption line”. The non-absorption line corresponds to a wavelength at which the amount of light absorbed by oxygen is smaller than the amount at the absorption lines.

Air is present around the radiation receiving object 90 in the processing apparatus 4, and oxygen is present in the optical path of the excimer laser beam. The laser apparatus 3 in the laser processing system 2 oscillates at a wavelength that does not coincide with any of the absorption lines of oxygen, that is, a non-absorption line of oxygen, for example, 193.40 nm. FIG. 2 shows a single-line oscillation spectrum at the wavelength of 193.40 nm. The wavelength of the excimer laser beam outputted from the laser apparatus 3 can be changed by changing the oscillation wavelength at which the semiconductor laser 20 oscillates. The outlined bidirectional arrow in FIG. 2 indicates that the oscillation spectrum is wavelength tunable.

1.4 Problems

To set an oscillation wavelength that does not coincide with any of the absorption lines of oxygen, a narrow spectral linewidth (about 0.3 pm) is required. However, a narrow spectral linewidth increases the temporal coherence, so that speckles are generated when the mask 80 is illuminated in Koehler illumination in the processing apparatus 4, resulting in a problem of deterioration in the condition of the laser radiation to the radiation receiving object 90.

To avoid the problem described above, the optical path difference prism 76 is essential as an optical system that reduces the coherence of the laser beam in the processing apparatus 4. However, for example, the coherence length of the beam having the spectral linewidth of about 0.3 pm is about 12.5 cm, and one rod of the optical path difference prism 76 is about 25 cm. The overall size of the optical path difference prism 76 is therefore greater than or equal to 1 meter, which is very large.

### 2. First Embodiment

### 2.1 Configuration

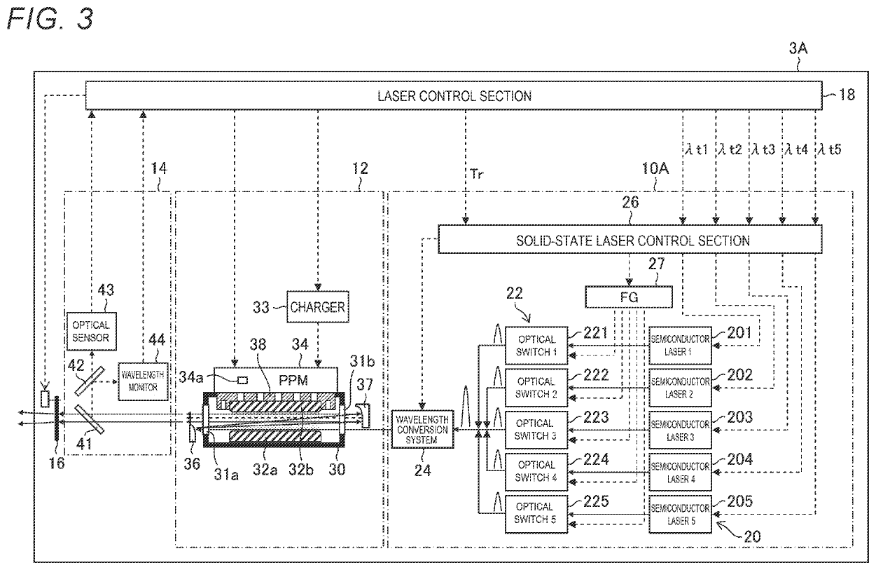

FIG. 3 schematically shows the configuration of a laser apparatus 3A according to a first embodiment. In the first embodiment, the laser apparatus 3A shown in FIG. 3 is used in place of the laser apparatus 3 described with reference to FIG. 1. The configuration shown in FIG. 3 will be described in terms of differences from the laser apparatus 3 shown in FIG. 1.

The laser apparatus 3A shown in FIG. 3 is a wavelength-tunable multiline ArF excimer laser apparatus including a wavelength-tunable multiline solid-state laser system 10A. In the present specification, the term “multiline” refers to a spectrum representing the distribution of optical intensity on a wavelength basis and having a plurality of peak wavelengths, and “multiline” is also called a “multiline spectrum”. The term “multiline” also means in some cases a laser beam having a multiline spectrum.

The wavelength-tunable multiline solid-state laser system 10A includes a plurality of semiconductor lasers 20 and a plurality of optical switches 22. The following description will be made of a case where five semiconductor lasers 20 are used and one optical switch 22 is disposed in the optical path of each of the semiconductor lasers 20, but the number of semiconductor lasers 20 and the number of optical switches 22 can each be any number that is greater than or equal to two as appropriate. The number of semiconductor lasers 20 and the number of optical switches 22 may be equal to each other.

It is assumed that the number of semiconductor lasers 20 is n, and the i-th semiconductor laser is referred to as “semiconductor laser 20i” with an index i that identifies the semiconductor laser 20 from the others. The parameter i is an integer greater than or equal to 1 but smaller than or equal to n. The parameter n is preferably greater than or equal to 3, and FIG. 3 shows an example where n=5. For example, a semiconductor laser 201 is the semiconductor laser having an index number i=1. The optical switch 22 disposed in the optical path of the semiconductor laser 20i is referred to as an “optical switch 22i”. For example, an optical switch 221 is the optical switch disposed in the optical path of the semiconductor laser 201.

In FIG. 3 and the following figures, the semiconductor laser 201 is referred to as a “semiconductor laser 1”, and the optical switch 221 is referred to as an “optical switch 1”. The last numeral in each of the notations represents the index i.

The configuration of each of the plurality of semiconductor lasers 201 to 205 is the same as that of the semiconductor laser 20 described with reference to FIG. 1. The configuration of each of the plurality of optical switches 221 to 225 is the same as that of the optical switch 22 described with reference to FIG. 1.

The wavelength-tunable multiline solid-state laser system 10A includes a light combiner that is not shown but is provided between the wavelength conversion system 24 and the plurality of optical switches 221 to 225. The light combiner combines the plurality of pulsed beams with one another in such a way that the optical paths of the pulsed beams outputted from the plurality of optical switches 221 to 225 substantially coincide with one another and causes the combined beam to enter the wavelength conversion system 24.

2.2 Operation

The operation of the laser apparatus 3A according to the first embodiment will be described. The laser radiation control section 58 transmits data on target wavelengths λt1, λt2, . . . , λtn and the target pulse energy Et to the laser control section 18. The target wavelengths λt1, λt2, . . . , λtn are target values of the plurality of peak wavelengths of the multiline pulsed laser beam outputted from the wavelength conversion system 24.

When the laser control section 18 receives the data on the target wavelengths λt1, λt2, . . . , λtn and the target pulse energy Et from the laser radiation control section 58, the laser control section 18 transmits the data on the target wavelengths λt1, λt2, . . . , λtn to the solid-state laser control section 26 and sets the charging voltage in the charger 33 in such a way that the target pulse energy Et is achieved.

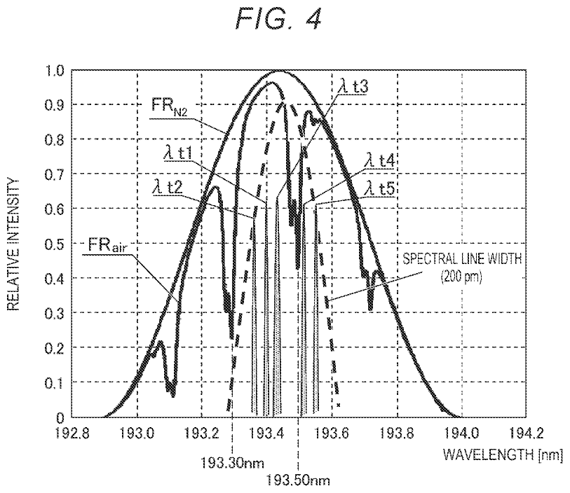

FIG. 4 is a graph showing an example of the spectrum of the multiline pulsed laser beam outputted from the wavelength conversion system 24. The spectral waveform drawn with the thick dashed line in FIG. 4 represents an effective spectrum of the excimer laser beam outputted from the laser apparatus 3A.

The target wavelengths λt1, λt2, . . . , λtn are wavelengths at which the amplifier 12 can perform the amplification and do not coincide with any of the absorption lines of oxygen. That is, the target wavelengths λt1, λt2, . . . , λtn are wavelengths different from the absorption lines of oxygen. For example, the target wavelength λt1 is 193.40 nm, which does not coincide with any of the absorption lines of oxygen, as shown in FIG. 4. The other target wavelengths λt2, . . . , λtn are set at wavelengths that cause the excimer laser beam to have, for example, an effective spectral linewidth of 200 μm.

When the data on the target wavelengths λt1, λt2, . . . , λtn are inputted to the solid-state laser control section 26 from the laser control section 18, the solid-state laser control section 26 controls the settings of the temperatures of the plurality of semiconductor lasers 201 to 205 in such a way that the multiline pulsed laser beam outputted from the wavelength conversion system 24 have peak wavelengths of λt1, λt2, . . . , λtn at the multiple lines. That is, the laser control section 18 and the solid-state laser control section 26 specify the oscillation wavelengths at which the plurality of semiconductor lasers 201 to 205 oscillate. The oscillation wavelength 2d, which is expressed by using the index i, is the oscillation wavelength at which the semiconductor laser 20i oscillates. In the present example, the oscillation wavelength λi is four times longer than the target wavelength λti.

That is, the following relationships are satisfied.

$$λ 1 = 4 λ t 1$$

$$λ 2 = 4 λ t 2$$

$$⋮$$

$$λ n = 4 λ t n$$

The plurality of semiconductor lasers 201 to 205 output laser beams having oscillation wavelengths λi different from one another.

The solid-state laser control section 26 further controls the two rotary stages, which are not shown in the figures, in such a way that the laser beam is incident on the rotary stages at angles of incidence that maximize the wavelength conversion efficiency of the LBO and KBBF crystals that are not shown in the wavelength conversion system 24.

When the light emission trigger signal Tr is inputted to the solid-state laser control section 26 from the laser control section 18, the solid-state laser control section 26 transmits signals to the plurality of optical switches 221 to 225 via the function generator 27. That is, the solid-state laser control section 26 specifies the timing at which the laser beam incident on each of the plurality of optical switches 221 to 225 is converted into pulses. As a result, the wavelength conversion system 24 outputs a multiline pulsed laser beam having peak wavelengths equal to the target wavelengths λt1, λt2, . . . , λtn.

In the case of the multiline spectrum shown in FIG. 4 by way of example, the target wavelengths λt1, λt2, and λt3 are set at non-absorption lines between the absorption lines P(17) and R(21). The target wavelengths λt4 and λt5 are set at non-absorption lines between the absorption lines P(19) and R(23). The absorption lines R(21) and P(19) are present between λt3 and λt4. Setting the target wavelengths λt1, λt2, . . . , λtn in such a way that the absorption lines fall within the region between at least any two of the plurality of peak wavelengths in the multiline spectrum allows generation of an excimer laser beam having an effective spectral linewidth as wide as about 200 μm.

Causing the maximum and minimum wavelengths of the plurality of target wavelengths λt1, λt2, . . . , λtn corresponding to the plurality of peak wavelengths in the multiline spectrum to fall within an allowable range over which the wavelength conversion system 24 can perform phase matching allows the single (common) wavelength conversion system 24 to generate wavelength-converted beams at the lines in the multiline spectrum.

The difference between the maximum and minimum wavelengths of the plurality of target wavelengths λt1, λt2, . . . , λtn corresponding to the plurality of peak wavelengths in the multiline spectrum is close to the spectral linewidth of the final amplified excimer laser beam outputted from the amplifier 12. In the example shown in FIG. 4, the maximum wavelength is λt5, and the minimum wavelength is λt2, so that the difference therebetween (λt5−λt2) is approximately 200 μm.

The beams generated by the wavelength conversion performed by the wavelength conversion system 24 and having the wavelengths corresponding to the target wavelengths λt1, λt2, . . . , λtn are an example of the “wavelength-converted beam” in the present disclosure.

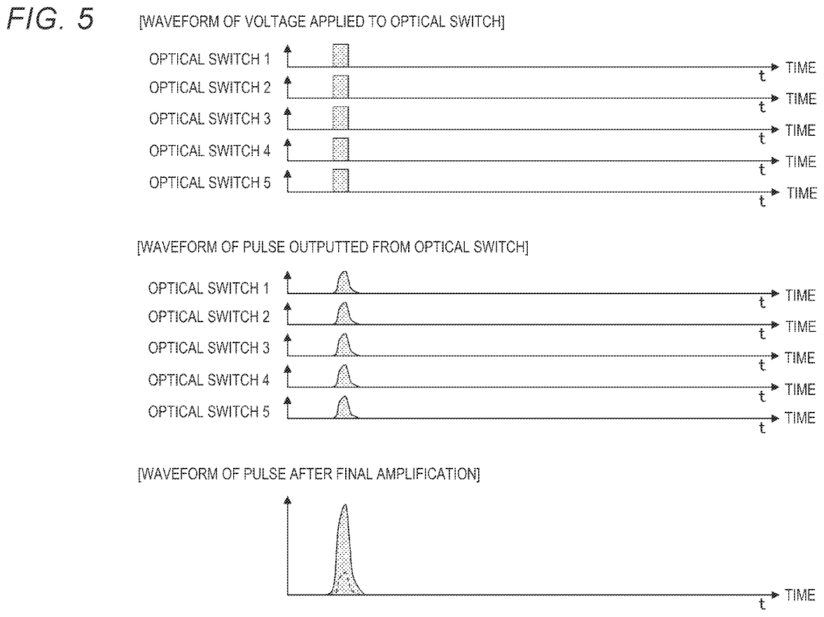

FIG. 5 is a timing chart showing an example of the operation of the plurality of optical switches 221 to 225. FIG. 5 shows the waveform of the voltage applied to each of the optical switches 221 to 225, the pulse waveform of the pulsed beam outputted from each of the optical switches 221 to 225, and the pulse waveform after the final amplification performed by the amplifier 12.

A voltage having a rectangular waveform is applied to each of the optical switches 221 to 225. The amplification factor of each of the optical switches can be changed by adjusting the magnitude of the voltage waveform. FIG. 5 shows that the five optical switches 221 to 225 have the same amplification factor, and the amplification factor of each of the optical switches 22 may be adjusted in accordance with the oscillation wavelength of the ArF excimer laser beam amplified by the amplifier 12.

For example, in the example shown in FIG. 4, in which the oscillation intensity is amplified by the amplifier 12, an oscillation intensity I(λt1) at the wavelength λt1 is greater than an oscillation intensity I(λt2) at the wavelength λt2, and an oscillation intensity I (λt3) at the wavelength λt3 is greater than an oscillation intensity I(λt4) at the wavelength λt4 and an oscillation intensity I(λt5) at the wavelength λt5.

The amplification factor of each of the optical switches 221 to 225 may be so adjusted that the output from the amplifier 12 has a desired spectral waveform in consideration of the amplification factor achieved by the combination of the optical switch 22 and the amplifier 12. At a wavelength where the amplification factor of the amplifier 12 is relatively higher, the amplification factor of the optical switch 22 can be made relatively lower. Since the pulse amplification and the timing thereof can be controlled by using the plurality of optical switches 221 to 225, pulse waveforms suitable for the processing can be generated.

When the laser control section 18 receives the light emission trigger signal Tr from the laser radiation control section 58, the laser control section 18 transmits trigger signals to the switch 34a of the pulse power module 34 and the optical switches 221 to 225, so that the discharge occurs when the pulsed laser beam outputted from the wavelength-tunable multiline solid-state laser system 10A enters the discharge space of the laser chamber 30 of the amplifier 12.

As a result, the pulsed laser beam outputted from the wavelength-tunable multiline solid-state laser system 10A undergoes the three-pass amplification performed by the amplifier 12.

The pulsed laser beam amplified by the amplifier 12 is sampled by the first beam splitter 41 of the monitor module 14, and the optical sensor 43 and the wavelength monitor 44 measure the pulse energy E and the wavelength λ, respectively.

The laser control section 18 controls the charging voltage to be applied to the charger 33 and the oscillation wavelength at which the semiconductor lasers 201 to 205 oscillate in such a way that the difference between the pulse energy E and the target pulse energy Et and the difference between the wavelength λ and the target wavelength λtn approach zero. A narrow spectral linewidth is required at each of the target wavelengths λt1, λt2, . . . , λtn so as not to coincide with the absorption lines of oxygen, as described above. It is therefore desirable to set the resolution of the wavelength monitor 44 of the monitor module 14, for example, at a value smaller than or equal to 0.3 pm.

The pulsed laser beam having passed through the first beam splitter 41 enters the processing apparatus 4 via the shutter 16. The operation of the processing apparatus 4 is the same as that in the example described with reference to FIG. 1.

The laser control section 18 and the solid-state laser control section 26 are an example of the “controller” in the present disclosure.

2.3 Effects and Advantages

According to the first embodiment, the pulsed laser beam outputted from the laser apparatus 3A has the wide effective spectral linewidth of 200 pm, which reduces the temporal coherence, so that the coherence length is shortened to as short as 0.2 mm. The speckles can thus be reduced during processing under Koehler illumination. As a result, the optical path difference prism 76, which is a coherence lowering optical system in the processing apparatus 4, can be made smaller than a typical optical element, whereby laser processing using mask transfer can be performed.

### 3. Second Embodiment

### 3.1 Configuration

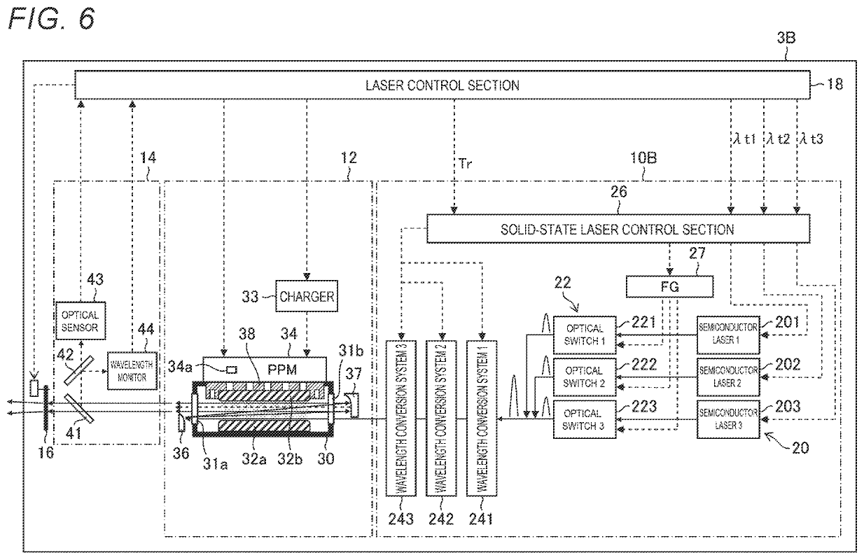

FIG. 6 schematically shows the configuration of a laser apparatus 3B according to a second embodiment. In the second embodiment, the laser apparatus 3B shown in FIG. 6 is used in place of the laser apparatus 3A described with reference to FIG. 3. The configuration shown in FIG. 6 will be described in terms of differences from the laser apparatus 3A shown in FIG. 3. The description of the second embodiment will be made of a case where the spectral linewidth of the pulsed laser beam outputted by the laser apparatus 3B is further widened to a value greater than 200 pm, as compared with the first embodiment.

The laser apparatus 3B shown in FIG. 6 is a wavelength-tunable multiline ArF excimer laser apparatus including a wavelength-tunable multiline solid-state laser system 10B.

The wavelength-tunable multiline solid-state laser system 10B includes a plurality of semiconductor lasers 201 to 203, a plurality of optical switches 221 to 223 and a plurality of wavelength conversion systems 241 to 243. The number of wavelength conversion systems 241 to 243 may be equal to the number of semiconductor lasers 20. The following description will be made of a case where n=3.

The plurality of wavelength conversion systems 241 to 243 are arranged in series in the optical path of the pulsed laser beam that is the superposition of pulsed beams outputted from the plurality of optical switches 221 to 223. The configuration of each of the wavelength conversion systems 241 to 243 may be the same as the configuration of the wavelength conversion system 24 described with reference to FIG. 3.

In FIG. 6, the wavelength conversion system 241 is referred to as a “wavelength conversion system 1”, the wavelength conversion system 242 as a “wavelength conversion system 2”, and the wavelength conversion system 243 as a “wavelength conversion system 3”.

3.2 Operation

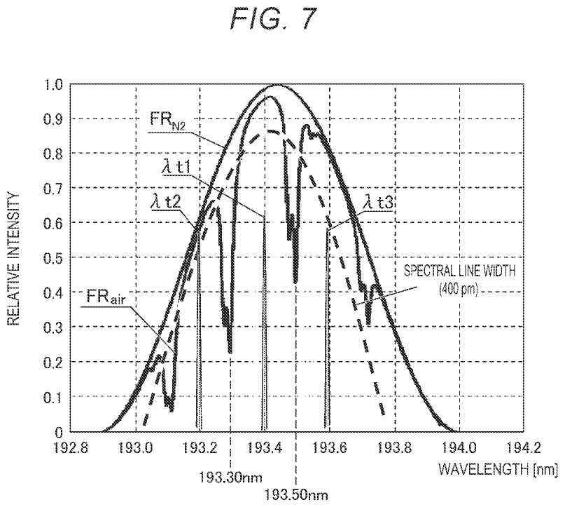

FIG. 7 is a graph showing an example of the spectrum of the multiline pulsed laser beam outputted from the wavelength-tunable multiline solid-state laser system 10B. The imaginary spectral waveform drawn with the thick dashed line in FIG. 7 represents an effective spectrum of the excimer laser beam outputted from the laser apparatus 3B.

The target wavelengths λt1, λt2, . . . , λtn are wavelengths at which the amplifier 12 can perform the amplification and do not coincide with any of the absorption lines of oxygen. For example, the target wavelength λt1 is 193.40 nm, which does not coincide with any of the absorption lines of oxygen, as shown in FIG. 7. The other target wavelengths λt2, . . . λtn are set at wavelengths that cause the excimer laser beam outputted from the laser apparatus 3B to have, for example, the spectral linewidth greater than 200 pm. The following description will be made of a case where an excimer laser beam having a spectral linewidth of approximately 400 pm is generated. Specifically, for example, the target wavelength λt2 may be set at 193.20 nm, which does not coincide with any of the absorption lines of oxygen, and the target wavelength λt3 may be set at 193.60 nm, which does not coincide with any of the absorption lines of oxygen, as shown in FIG. 7.

That is, the target wavelengths are each so set that the difference between the maximum and minimum wavelengths of the plurality of target wavelengths λt1, λt2, . . . λtn corresponding to the plurality of peak wavelengths in the multiline spectrum is greater than 200 pm, for example, the difference is 400 μm.

In the example shown in FIG. 7, the target wavelength λt1 is set at a non-absorption line between the absorption lines P(17) and R(21). The target wavelength λt2 is set at a non-absorption line between the absorption lines P(15) and R(19). The target wavelength λt3 is set at a non-absorption line between the absorption lines P(19) and R(23).

The absorption lines R(19) and P(17) are present between λt1 and λt2, and the absorption lines R(21) and P(19) are present between λt1 and λt3.

When the data on the target wavelengths λt1, λt2, . . . λtn are inputted to the solid-state laser control section 26 from the laser control section 18, the solid-state laser control section 26 controls the settings of the temperatures of the plurality of semiconductor lasers 201 to 20n in such a way that the pulsed laser beams outputted from the wavelength conversion systems 241, 242, . . . 24n have the wavelengths of λt1, λt2, . . . , λtn.

The solid-state laser control section 26 further controls the two rotary stages, which are not shown in the figures, in each of the wavelength conversion systems 241 to 24n in such a way that the laser beam is incident on the rotary stages at angles of incidence that maximize the wavelength conversion efficiency of the LBO and KBBF crystals in each of the wavelength conversion systems 241, 242, . . . 24n.

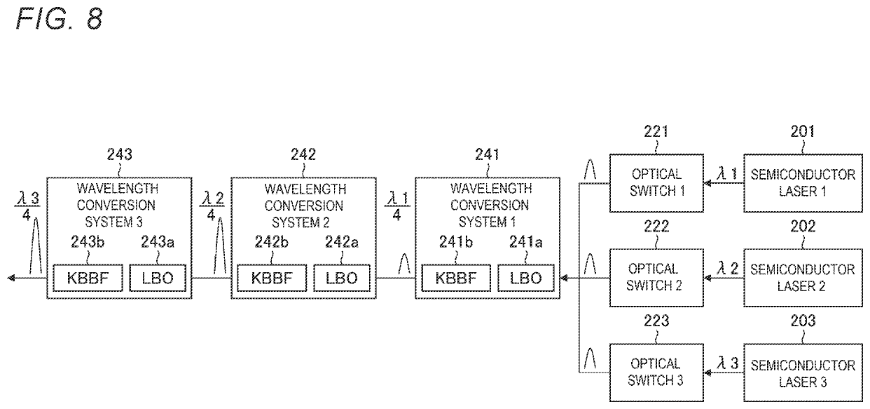

FIG. 8 schematically shows the operation of the plurality of wavelength conversion systems 241 to 243. Out of the plurality of wavelength conversion systems 241 to 243 arranged in series in the optical path of the laser beam, the wavelength conversion system 241 in the first stage generates the fourth harmonic of the pulsed laser beam having the wavelength λ1 and outputted from the optical switch 221. The wavelength conversion system 241 includes an LBO crystal 241a and a KBBF crystal 241b. The solid-state laser control section 26 controls the two rotary stages, which are not shown in the figures, in such a way that the laser beam is incident on the rotary stages at angles of incidence that maximize the wavelength conversion efficiency of the LBO crystal 241a and the KBBF crystal 241b in the wavelength conversion system 241.

The pulsed laser beam having the wavelength λ2 and outputted from the optical switch 222 and the pulsed laser beam having the wavelength λ3 and outputted from the optical switch 223 pass through the wavelength conversion system 241.

The wavelength conversion system 242 in the second stage generates the fourth harmonic of the pulsed laser beam having the wavelength 22 and outputted from the optical switch 222. The wavelength conversion system 242 includes an LBO crystal 242a and a KBBF crystal 242b. The solid-state laser control section 26 controls the two rotary stages, which are not shown in the figures, in such a way that the laser beam is incident on the rotary stages at angles of incidence that maximize the wavelength conversion efficiency of the LBO crystal 242a and the KBBF crystal 242b in the wavelength conversion system 242.

Similarly, the wavelength conversion system 243 in the third stage generates the fourth harmonic of the pulsed laser beam having the wavelength 23 and outputted from the optical switch 223. The wavelength conversion system 243 includes an LBO crystal 243a and a KBBF crystal 243b. The solid-state laser control section 26 controls the two rotary stages, which are not shown in the figures, in such a way that the laser beam is incident on the rotary stages at angles of incidence that maximize the wavelength conversion efficiency of the LBO crystal 243a and the KBBF crystal 243b in the wavelength conversion system 243.

The wavelength conversion performed by the plurality of wavelength conversion systems 241 to 243 generates the fourth harmonic beams, which are the wavelength-converted beams corresponding to the oscillation wavelengths λ1, λ2, and λ3, and the wavelength conversion system 243 in the final stage outputs the multiline pulsed laser beam.

The beams having the wavelengths corresponding to the target wavelengths λt1, λt2, and λt3 generated by the wavelength conversion performed by the wavelength conversion systems 241 to 243 are an example of the “wavelength-converted beam” in the present disclosure.

3.3 Effects and Advantages

According to the second embodiment, the pulsed laser beam outputted from the laser apparatus 3B has an effective spectral linewidth effectively greater than 200 pm, for example, about 400 pm, which reduces the temporal coherence and reduces speckles during the processing under Koehler illumination. As a result, the optical path difference prism 76, which serves as the coherence lowering optical system in the processing apparatus 4, can be made smaller than a typical optical element, whereby laser processing using mask transfer can be performed.

The self oscillation spectral waveform FR_{N2} in the nitrogen gas has the spectral linewidth of about 450 pm as full width at half maximum (FWHM), as described with reference to FIG. 2. The difference between the maximum and minimum wavelengths of the peak wavelengths at the lines of pulsed laser beam outputted from the laser apparatus 3B may therefore be smaller than or equal to 450 pm. Reducing the difference between the maximum and minimum wavelengths to a value smaller than or equal to 450 pm allows the lines of the outputted pulsed laser beam to be wavelengths at which the ArF excimer laser amplifier can perform the amplification.

Since the effective spectral linewidth in the second embodiment is further wider than that in the first embodiment, the speckle reduction effect is further improved, whereby the optical path difference prism 76 can be made further compact.

3.4 Variations

In FIG. 6, the case where the plurality of wavelength conversion systems 241 to 243 are arranged in series along the optical path has been described. To perform the wavelength conversion before the pulsed beams outputted from the optical switches 221 to 223 are combined with one another, the wavelength conversion systems 241 to 243 may be disposed in the optical paths of the optical switches 221 to 223.

### 4. Variations of Wavelength-Tunable Multiline Solid-State Laser System

### 4.1 Example Using Titanium-Sapphire Amplifier

### 4.1.1 Configuration

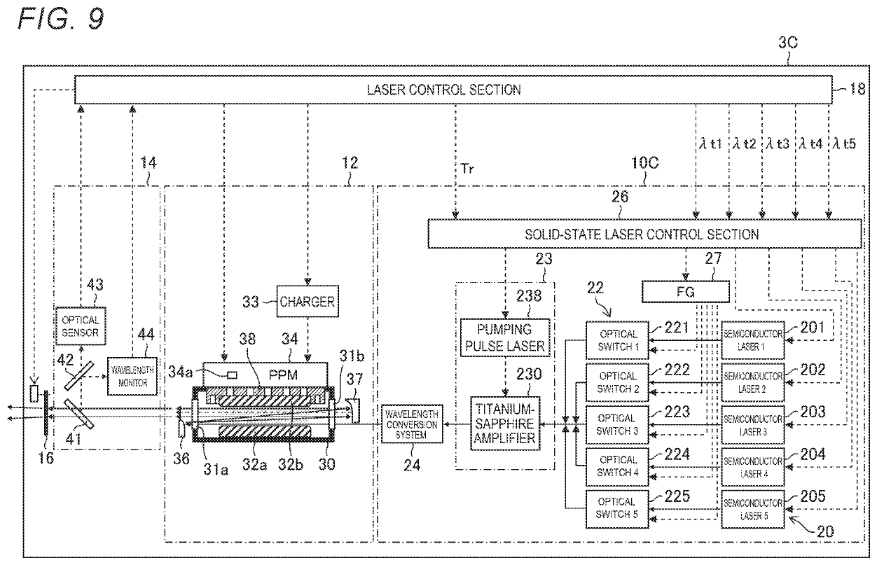

FIG. 9 schematically shows an example of the configuration of a wavelength-tunable multiline solid-state laser system 10C using a titanium-sapphire amplifier. In place of the wavelength-tunable multiline solid-state laser system 10A in FIG. 3 and the wavelength-tunable multiline solid-state laser system 10B in FIG. 7, the wavelength-tunable multiline solid-state laser system 10C in FIG. 9 may be employed. A laser apparatus 3C shown in FIG. 9 is a wavelength-tunable multiline ArF excimer laser apparatus including the wavelength-tunable multiline solid-state laser system 10C. Differences in configuration between FIGS. 9 and 3 will be described.

The wavelength-tunable multiline solid-state laser system 10C includes a plurality of semiconductor lasers 201 to 205, which each output a seed beam, a plurality of optical switches 221 to 225, which each convert the seed beam into a predetermined pulsed beam, a titanium-sapphire amplifier 23, which amplifies the seed beams, the wavelength conversion system 24, and the solid-state laser control section 26, as shown in FIG. 9. The titanium-sapphire amplifier 23 is an example of the “optical amplifier” in the present disclosure.

The titanium-sapphire amplifier 23 includes a titanium-sapphire crystal 230 and a pumping pulse laser 238. The titanium-sapphire crystal 230 is disposed in the optical path of the seed beams. The pumping pulse laser 238 may, for example, be a laser apparatus that outputs the second harmonic of the beam from a YLF laser. “YLF” stands for yttrium lithium fluoride, and the chemical formula thereof corresponds to LiYF₄.

4.1.2 Advantages

According to the configuration shown in FIG. 9, a high-power solid-state laser system can be constructed because the fundamental wave can be amplified by using the titanium-sapphire amplifier.

4.2 Example Using Second Harmonic Generator in Wavelength Conversion System

4.2.1 Configuration

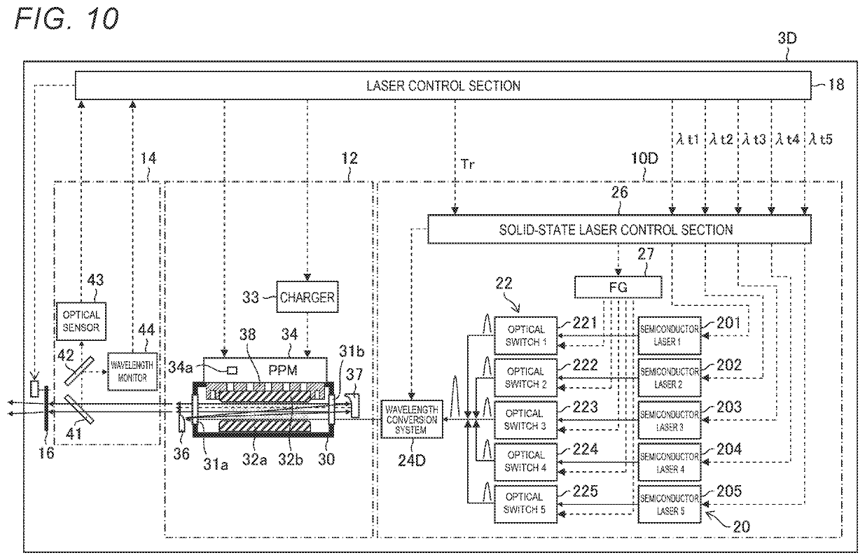

FIG. 10 schematically shows an example of the configuration of a wavelength-tunable multiline solid-state laser system 10D using a second harmonic generator. In place of the wavelength-tunable multiline solid-state laser system 10A in FIG. 3 and the wavelength-tunable multiline solid-state laser system 10B in FIG. 7, the wavelength-tunable multiline solid-state laser system 10D in FIG. 10 may be employed. A laser apparatus 3D shown in FIG. 10 is a wavelength-tunable multiline ArF excimer laser apparatus including the wavelength-tunable multiline solid-state laser system 10D. Differences in configuration between FIGS. 10 and 3 will be described.

The wavelength-tunable multiline solid-state laser system 10D includes a plurality of semiconductor lasers 201 to 205, which each output a seed beam, a plurality of optical switches 221 to 225, which each convert the seed beam into a predetermined pulsed beam, a wavelength conversion system 24D, and the solid-state laser control section 26, as shown in FIG. 10.

The semiconductor lasers 201 to 205 shown in FIG. 10 are each a distributed feedback semiconductor laser that outputs a laser beam having a wavelength of about 386.8 nm.

The wavelength conversion system 24D is a wavelength conversion system that generates a second harmonic and includes a KBBF crystal that is not shown. The wavelength conversion system 24D is an example of a second harmonic generator.

The KBBF crystal converts the pulsed laser beam outputted from each of the optical switches 221 to 225 and having the wavelength of about 386.8 nm into a pulsed laser beam having the wavelength of about 193.4 nm, which is second harmonic of the incident pulsed laser beam.

4.2.2 Advantages

According to the configuration shown in FIG. 10, only one nonlinear crystal (KBBF crystal) as the wavelength conversion system 24D can generate a pulsed laser beam having the wavelength of about 193.4 nm.

4.3 Example 1 Using Two Types of Fiber Lasers

### 4.3.1 Configuration

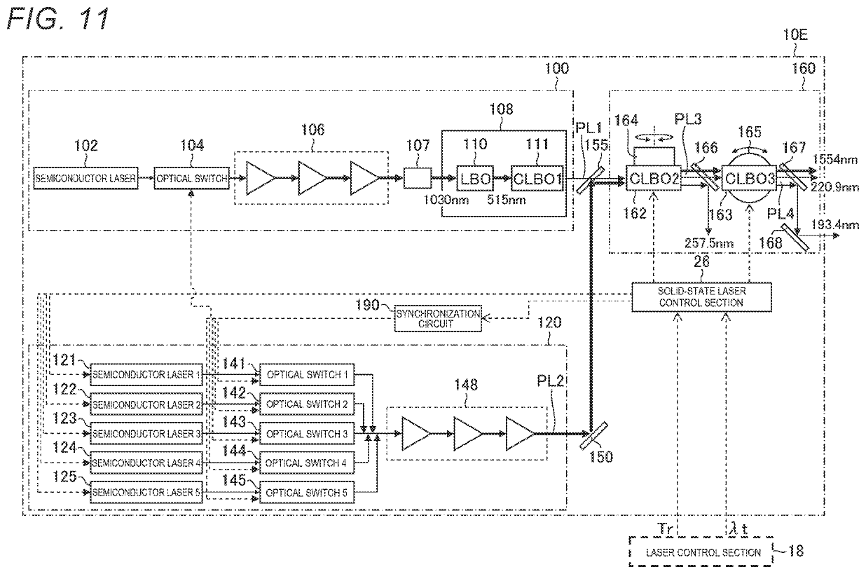

FIG. 11 schematically shows an example of the configuration of a wavelength-tunable multiline solid-state laser system 10E using two types of fiber lasers. In place of the wavelength-tunable multiline solid-state laser system 10A in FIG. 3, the wavelength-tunable multiline solid-state laser system 10E in FIG. 11 may be employed. Differences in configuration between FIGS. 11 and 3 will be described.

The wavelength-tunable multiline solid-state laser system 10E includes a first solid-state laser apparatus 100, a second solid-state laser apparatus 120, a high-reflectance mirror 150, a first dichroic mirror 155, a wavelength conversion system 160, a synchronization circuit 190, and the solid-state laser control section 26.

The first solid-state laser apparatus 100 includes a first semiconductor laser 102, a first optical switch 104, a first fiber amplifier 106, a solid-state amplifier 107, and a wavelength conversion system 108.

The first semiconductor laser 102 is a seed laser that operates in a single longitudinal mode and outputs a laser beam having a wavelength of about 1030 nm as a first seed beam based on CW oscillation. The first semiconductor laser 102 is, for example, a distributed feedback semiconductor laser. The first semiconductor laser 102 outputs beam having a wavelength changeable around about 1030 nm.

The first optical switch 104 is disposed in the optical path of the first seed beam outputted from the first semiconductor laser 102. The configuration of the first optical switch 104 is the same as that of the optical switch 22 described with reference to FIG. 1. The first optical switch 104 is, for example, a semiconductor optical amplifier, converts the first seed beam outputted from the first semiconductor laser 102 into pulses, and outputs a first pulsed beam. The first pulsed beam outputted from the first optical switch 104 is referred to as “first seed pulsed beam”.

The first fiber amplifier 106 is an Yb fiber amplifier in which a plurality of quartz fibers doped with Yb (Ytterbium) are connected to each other in the form of a cascade. The quartz fibers are an example of the “optical fiber” in the present disclosure. The solid-state amplifier 107 is a YAG (Yttrium Aluminum Garnet) crystal doped with Yb. The first fiber amplifier 106 and the solid-state amplifier 107 are each optically excited by a CW excitation beam inputted from a CW excitation semiconductor laser that is not shown.

The first fiber amplifier 106 and the solid-state amplifier 107 amplify the first seed pulsed beam outputted from the first optical switch 104. The amplified beam outputted from the solid-state amplifier 107 enters the wavelength conversion system 108. The first fiber amplifier 106 and the solid-state amplifier 107 are an example of the “first amplifier” in the present disclosure. The amplified beam outputted from the solid-state amplifier 107 is an example of the “first amplified beam” in the present disclosure.

The wavelength conversion system 108 is a wavelength conversion system that generates a fourth harmonic and includes an LBO crystal 110 and a first CLBO crystal 111. The term “CLBO” corresponds to the chemical formula CsLiB₆O₁₀. The first CLBO crystal 111 is referred to as “CLBO1” in FIG. 11.

The LBO crystal 110 and the first CLBO crystal 111 are disposed so as to generate a first pulsed laser beam PL1 having a wavelength of about 257.5 nm, which is the fourth harmonic of the beam having the wavelength of about 1030 nm. The wavelength conversion system 108 converts the first seed pulsed beam amplified by the first fiber amplifier 106 and the solid-state amplifier 107 into a fourth harmonic and outputs the fourth harmonic as the first pulsed laser beam PL1. The wavelength conversion system 108 is an example of the “first wavelength conversion system” in the present disclosure. The first pulsed laser beam PL1 is an example of the “first wavelength-converted beam” in the present disclosure.

The second solid-state laser apparatus 120 includes a plurality of semiconductor lasers 121 to 125, a plurality of optical switches 141 to 145, a combiner that is not shown, and a second fiber amplifier 148.

The plurality of first semiconductor lasers 121 to 125 are each a seed laser that operates in a single longitudinal mode and outputs a laser beam having a wavelength of about 1554 nm as a second seed beam based on CW oscillation. The plurality of semiconductor lasers 121 to 125 are, for example, each a distributed feedback semiconductor laser. The plurality of semiconductor lasers 121 to 125 can each output a beam having a wavelength changeable around 1554 nm. The plurality of semiconductor lasers 121 to 125 are each an example of the “second semiconductor laser” in the present disclosure.

The plurality of optical switches 141 to 145 are disposed in the optical paths of the plurality of respective semiconductor lasers 121 to 125. The configuration of each of the plurality of optical switches 141 to 145 is the same as that of the optical switch 22 described with reference to FIG. 1. The plurality of optical switches 141 to 145 are, for example, each a semiconductor optical amplifier, convert the second seed beams outputted from the plurality of semiconductor lasers 121 to 125 into pulses, and output second pulsed beams. The second pulsed beams outputted from the plurality of optical switches 141 to 145 are combined with one another by a combiner that is not shown, and the combined beam enters the second fiber amplifier 148. The second pulsed beams outputted from the plurality of optical switches 141 to 145 are referred to as “second seed pulsed beams”. The plurality of optical switches 141 to 145 are each an example of the “second optical switch” in the present disclosure.

The second fiber amplifier 148 is an Er fiber amplifier in which a plurality of quartz fibers (optical fiber) doped with Er (erbium) and Yb (Ytterbium) are connected to each other in the form of a cascade. The second fiber amplifier 148 includes a CW excitation semiconductor laser that is not shown. The second fiber amplifier 148 is an example of the “optical amplifier” and the “second optical amplifier” in the present disclosure, and Er and Yb are examples of the “impurity” in the present disclosure.

The second fiber amplifier 148 is optically excited by a CW excitation beam inputted from the CW excitation semiconductor laser. The second fiber amplifier 148 amplifies the second seed pulsed beam that enters the second fiber amplifier 148 via the combiner and outputs the amplified pulsed beam as a second pulsed laser beam PL2. The second pulsed laser beam PL2 is an example of the “second amplified beam” in the present disclosure.

The high-reflectance mirror 150 is so disposed as to reflect at high reflectance the second pulsed laser beam PL2 outputted from the second solid-state laser apparatus 120 and cause the second pulsed laser beam PL2 reflected at high reflectance to be incident on the first dichroic mirror 155.

The first dichroic mirror 155 is disposed in the position on which the first pulsed laser beam PL1 outputted from the first solid-state laser apparatus 100 is incident.

The first dichroic mirror 155 is coated with a film that transmits at high transmittance the first pulsed laser beam PL1 having the wavelength of about 257.5 nm and reflects at high reflectance the second pulsed laser beam PL2 having the wavelength of about 1554 nm. The first dichroic mirror 155 is so disposed that the optical path axis of the first pulsed laser beam PL1 transmitted at high transmission and the optical path axis of the second pulsed laser beam PL2 reflected at high reflection substantially coincide with each other.

The wavelength conversion system 160 includes a second CLBO crystal 162, a third CLBO crystal 163, a first rotary stage 164, a second rotary stage 165, a second dichroic mirror 166, a third dichroic mirror 167, and a high-reflectance mirror 168. In FIG. 11, the second CLBO crystal 162 is referred to as “CLBO2”, and the third CLBO crystal 163 is referred to as “CLBO3”.

The second CLBO crystal 162, the second dichroic mirror 166, the third CLBO crystal 163, and the third dichroic mirror 167 are arranged in this order along the optical path of the first pulsed laser beam PL1 and the second pulsed laser beam PL2.

The second CLBO crystal 162 is held on the first rotary stage 164. The first rotary stage 164 is a motorized stage that rotates the second CLBO crystal 162 and includes an actuator that is not shown but operates in accordance with an instruction from the solid-state laser control section 26. The axis of rotation of the first rotary stage 164 is parallel to the plane of view of FIG. 11 and perpendicular to the traveling direction of the first pulsed laser beam PL1. The direction of rotation around the axis of rotation of the first rotary stage 164 is called a direction θ. The first rotary stage 164 is driven to rotate in the direction θ in accordance with an instruction from the solid-state laser control section 26.

The third CLBO crystal 163 is held on the second rotary stage 165. The second rotary stage 165 is a motorized stage that rotates the third CLBO crystal 163. The axis of rotation of the second rotary stage 165 is perpendicular to the plane of view of FIG. 11. The direction of rotation around the axis of rotation of the second rotary stage 165 is called a direction φ. The second rotary stage 165 is driven to rotate in the direction φ in accordance with an instruction from the solid-state laser control section 26.

The first pulsed laser beam PL1 and the second pulsed laser beam PL2 enter the second CLBO crystal 162.

In the second CLBO crystal 162, the first pulsed laser beam PL1 and the second pulsed laser beam PL2 are superimposed on each other to generate a third pulsed laser beam PL3 having a wavelength of about 220.9 nm, which corresponds to the sum frequency produced from the wavelength of about 257.5 nm and the wavelength of about 1554 nm. The first pulsed laser beam PL1 and the second pulsed laser beam PL2 pass through the second CLBO crystal 162.

The second dichroic mirror 166 is coated with a film that reflects at high reflectance the first pulsed laser beam PL1 having the wavelength of about 257.5 nm and transmits at high transmittance the second pulsed laser beam PL2 and the third pulsed laser beam PL3. The second pulsed laser beam PL2 and the third pulsed laser beam PL3 having passed through the second dichroic mirror 166 at high transmittance enter the third CLBO crystal 163.

In the third CLBO crystal 163, the second pulsed laser beam PL2 and the third pulsed laser beam PL3 are superimposed on each other to generate a fourth pulsed laser beam PL4 having a wavelength of about 193.4 nm, which corresponds to the sum frequency produced from the wavelength of about 1554 nm and the wavelength of about 220.9 nm. The second pulsed laser beam PL2 and the third pulsed laser beam PL3 pass through the third CLBO crystal 163. The wavelength conversion system 160 is an example of the “second wavelength conversion system” in the present disclosure.

The third dichroic mirror 167 is coated with a film that reflects at high reflectance the fourth pulsed laser beam PL4 and transmits at high transmittance the second pulsed laser beam PL2 and the third pulsed laser beam PL3. The high-reflectance mirror 168 is so positioned as to reflect at high reflectance the fourth pulsed laser beam LP4 reflected off the third dichroic mirror 167 at high reflectance and cause the fourth pulsed laser beam PL4 to exit out of the wavelength conversion system 160.

The solid-state laser control section 26 is electrically connected to the first rotary stage 164 and the second rotary stage 165 and controls the operation of the first rotary stage 164 and the second rotary stage 165. The solid-state laser control section 26 is further electrically connected to the synchronization circuit 190. The synchronization circuit 190 may be incorporated in the solid-state laser control section 26.

The synchronization circuit 190 is electrically connected to the first optical switch 104 of the first solid-state laser apparatus 100 and the optical switches 141 to 145 of the second solid-state laser apparatus 120.

The synchronization circuit 190 controls the first optical switch 104 and the optical switches 141 to 145 based on a trigger signal inputted from the solid-state laser control section 26 to synchronize the generation timings of the seed pulsed beams from the first solid-state laser apparatus 100 and the second solid-state laser apparatus 120 with each other.

The solid-state laser control section 26 is electrically connected to the first semiconductor laser 102 of the first solid-state laser apparatus 100, the CW excitation semiconductor laser provided in the first fiber amplifier 106, the semiconductor lasers 121 to 125 of the second solid-state laser apparatus 120, and the CW excitation semiconductor laser provided in the second fiber amplifier 148 via signal lines that are not shown in the figures.

The solid-state laser control section 26 receives a laser oscillation preparation signal, the light emission trigger signal, the data on the target wavelength, and other pieces of information from the laser radiation control section 58 of the processing apparatus 4 via the laser control section 18 and controls the first rotary stage 164, the second rotary stage 165, the synchronization circuit 190, the first semiconductor laser 102, the semiconductor lasers 121 to 125, and other components.

4.3.2 Operation

The operation of the wavelength-tunable multiline solid-state laser system 10E will be described. When the data on the target wavelength λt is inputted to the solid-state laser control section 26 from the laser control section 18, the solid-state laser control section 26 fixes the oscillation wavelength at which the first semiconductor laser 102 in the first solid-state laser apparatus 100 oscillates in such a way that the laser beam outputted from the wavelength conversion system 160 has the wavelength λt and changes the oscillation wavelength at which each of the plurality of semiconductor lasers 121 to 125 in the second solid-state laser apparatus 120 oscillates in such a way that the effective spectral linewidth is 200 μm. In this process, λt is formed of a plurality of pieces of wavelength data, λt1, λt2, . . . , λtn.

The solid-state laser control section 26 controls the first rotary stage 164 and the second rotary stage 165 in such a way that the laser beam is incident on the rotary stages at angles of incidence that maximize the wavelength conversion efficiency at the second CLBO crystal 162 and the third CLBO crystal 163 in the wavelength conversion system 160.

The solid-state laser control section 26 transmits a signal to the synchronization circuit 190 when the light emission trigger signal Tr is inputted to the solid-state laser control section 26 from the laser control section 18.

The synchronization circuit 190 provides sync signals to the first optical switch 104 and the optical switches 141 to 145 in such a way that the first pulsed laser beam PL1 outputted from the first solid-state laser apparatus 100 and the second pulsed laser beam PL2 outputted from the second solid-state laser apparatus 120 enter the second CLBO crystal 162 of the wavelength conversion system 160 at approximately the same time.

As a result, the wavelength conversion system 160 outputs the fourth pulsed laser beam PL4 having the target wavelength λt.

Let λp1 be the wavelength of the first pulsed laser beam PL1 outputted from the first solid-state laser apparatus 100, λp2 be the wavelength of the second pulsed laser beam PL2 outputted from the second solid-state laser apparatus 120, and λp3 be the wavelength after the wavelength conversion performed by the third CLBO crystal 163 in the wavelength conversion system 160, and the following equation is satisfied from the sum frequency generation scheme.

4/λp1+2/λp2=1/λp3 (Expression 1)

The wavelength of the beam from the first solid-state laser apparatus 100 and the wavelength of the beam from the second solid-state laser apparatus 120 for the wavelength conversion of generating a pulsed laser beam having the target wavelength λt can be determined from Expression 1.

Specifically, the wavelength of the beam from the first solid-state laser apparatus 100 is roughly so adjusted that the target wavelength λt is achieved, and the wavelength of the beam from the second solid-state laser apparatus 120 is so precisely adjusted that the target wavelength λt is achieved.

For example, when the target wavelength λt is 193.4 nm, λp1 is set at 1031 nm, and λp2 is adjusted to 1555 nm. When the target wavelength λt is 193.6 nm, λp1 is set at 1031 nm, and λp2 is adjusted to 1550 nm. In this process, the plurality of semiconductor lasers 121 to 125 each output a second seed beam having the wavelength λp2 or a wavelength close thereto.

The operation of controlling the oscillation wavelength at which the plurality of semiconductor lasers 121 to 125 each oscillate in accordance with the target wavelengths λt1, λt2, . . . , λtn of the peak wavelengths at the multiple lines of the beam outputted from the wavelength conversion system 160 is the same as that in the example described in the first embodiment. That is, the oscillation wavelength at which the semiconductor lasers 121 to 125 each oscillate is so set that the peak wavelengths of the multiline pulsed laser beam, which is the wavelength-converted beam outputted from the wavelength conversion system 160, differ from the absorption lines of oxygen.

4.3.3 Variations

In FIG. 11, the second solid-state laser apparatus 120 has been described with reference to the configuration including the plurality of semiconductor lasers 121 to 125 and the plurality of optical switches 141 to 145, and the first solid-state laser apparatus 100 may instead include a plurality of semiconductor lasers and a plurality of optical switches. In this case, the portion of the wavelength conversion system 108 in the first solid-state laser apparatus 100 is changed to include a plurality of wavelength conversion systems arranged in series.

4.4 Example 2 Using Two Types of Fiber Lasers

### 4.4.1 Configuration

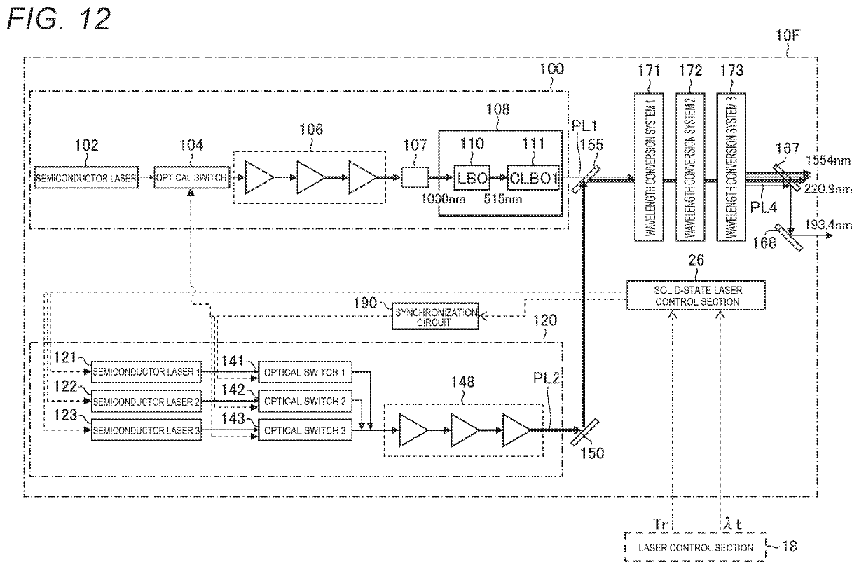

FIG. 12 schematically shows an example of the configuration of a wavelength-tunable multiline solid-state laser system 10F using two types of fiber lasers. In place of the wavelength-tunable multiline solid-state laser system 10B in FIG. 6, the wavelength-tunable multiline solid-state laser system 10F in FIG. 12 may be employed. Differences in configuration between FIGS. 12 and 11 will be described.

The wavelength-tunable multiline solid-state laser system 10F shown in FIG. 12 is employed when the spectral linewidth of the pulsed laser beam outputted by the laser apparatus 3B is widened to a value greater than 200 μm. The wavelength tunable multiline solid-state laser system 10F shown in FIG. 12 includes a plurality of semiconductor lasers 121 to 123, a plurality of optical switches 141 to 143 and a plurality of wavelength conversion systems 171 to 173. The number of wavelength conversion systems 171 to 173 may be equal to the number of semiconductor lasers provided in the second solid-state laser apparatus 120. The following description will be made of a case where n=3.

The plurality of wavelength conversion systems 171 to 173 are arranged in series along the optical path of the first pulsed laser beam PL1 and the second pulsed laser beam PL2 having exited out of the first dichroic mirror 155. The configuration of each of the wavelength conversion systems 171 to 173 may be the same as the configuration of the wavelength conversion system 160 described with reference to FIG. 11. The wavelength conversion systems 171 to 173 are an example of the “second wavelength conversion system” in the present disclosure.

In FIG. 12, the wavelength conversion system 171 is referred to as a “wavelength conversion system 1”, the wavelength conversion system 172 as a “wavelength conversion system 2”, and the wavelength conversion system 173 as a “wavelength conversion system 3”.

4.4.2 Operation

The operation of the wavelength-tunable multiline solid-state laser system 10F will be described. When the data on the target wavelength λt is inputted to the solid-state laser control section 26 from the laser control section 18, the solid-state laser control section 26 fixes the oscillation wavelength at which the first semiconductor laser 102 in the first solid-state laser apparatus 100 oscillates in such a way that the laser beams outputted from the wavelength conversion systems 171 to 173 each have the wavelength λt and changes the oscillation wavelength at which each of the plurality of semiconductor lasers 121 to 123 in the second solid-state laser apparatus 120 oscillates in such a way that the effective spectral linewidth is greater than 200 pm (400 pm, for example). In this process, λt is formed of a plurality of pieces of wavelength data, λt1, λt2, . . . , λtn.

The solid-state laser control section 26 controls the two rotary stages in the wavelength conversion systems 171 to 173, which are not shown in the figures, in such a way that the laser beam is incident on the rotary stages at angles of incidence that maximize the wavelength conversion efficiency of the two CLBO crystals in each of the plurality of wavelength conversion systems 171 to 173. The rest of the operation is the same as the operation of the configuration shown in FIG. 11.

The solid-state laser control section 26 transmits the light emission trigger signal Tr to the synchronization circuit 190 when the signal is inputted to the solid-state laser control section 26 from the laser control section 18.

The synchronization circuit 190 provides the optical switch 104 and the optical switches 141 to 143 with sync signals in such a way that the first pulsed laser beam PL1 outputted from the first solid-state laser apparatus 100 and the second pulsed laser beam PL2 outputted from the second solid-state laser apparatus 120 enter the second CLBO crystal 162 of the wavelength conversion system 171 at approximately the same time.

As a result, the last one of the plurality of wavelength conversion systems 171 to 173 outputs the fourth pulsed laser beam PL4 having the target wavelength λt.

The wavelength of the beam from the first solid-state laser apparatus 100 and the wavelength of the beam from the second solid-state laser apparatus 120 for the wavelength conversion of generating a pulsed laser beam having the target wavelength λt can be determined from Expression 1.

Specifically, the wavelength of the beam from the first solid-state laser apparatus 100 is roughly so adjusted that the target wavelength λt is achieved, and the wavelength of the beam from the second solid-state laser apparatus 120 is so precisely adjusted that the target wavelength λt is achieved.

For example, when the target wavelength λt is 193.2 nm, λp1 is set at 1030 nm, and λp2 is adjusted to 1547.4 nm. When the target wavelength λt is 193.4 nm, λp1 is set at 1030 nm, and λp2 is adjusted to 1553.85 nm. When the target wavelength λt is 193.6 nm, λp1 is set at 1030 nm, and λp2 is adjusted to 1560.3 nm. In this process, the plurality of semiconductor lasers 121 to 123 each output a second seed beam having the wavelength λp2 or a wavelength close thereto.

The operation of controlling the oscillation wavelength at which the plurality of semiconductor lasers 121 to 123 each oscillate in accordance with the target wavelengths λt1, λt2, . . . , λtn of the peak wavelengths at the multiple lines of the beam outputted from the plurality of wavelength conversion systems 171 to 173 is the same as that in the example described in the second embodiment. That is, the oscillation wavelength at which the semiconductor lasers 121 to 123 each oscillate is so set that the peak wavelengths of the multiline pulsed laser beam, which is the wavelength-converted beam generated by the plurality of wavelength conversion systems 171 to 173, differ from the absorption lines of oxygen.

4.4.3 Variations

In FIG. 12, the second solid-state laser apparatus 120 has been described with reference to the configuration including the plurality of semiconductor lasers 121 to 123 and the plurality of optical switches 141 to 143, and the first solid-state laser apparatus 100 may instead include a plurality of semiconductor lasers and a plurality of optical switches. In this case, the portion of the wavelength conversion system 108 in the first solid-state laser apparatus 100 is changed to include a plurality of wavelength conversion systems arranged in series.

5. Method for Manufacturing Electronic Device

A laser processing system that is the combination of the laser apparatus 3A described in FIG. 3 and the processing apparatus 4 described in FIG. 1 can be used to manufacture semiconductor devices by carrying out a plurality of steps after transferring a device pattern onto a semiconductor wafer as the radiation receiving object 90. In place of the laser apparatus 3A, the laser processing system may use the laser apparatus 3B described with reference to FIG. 6, the laser apparatus 3C described with reference to FIG. 9, or the laser apparatus 3D described with reference to FIG. 10. Furthermore, the wavelength-tunable multiline solid-state laser system 10E described with reference to FIG. 11 may be employed in place of the wavelength-tunable multiline solid-state laser systems 10A, 10C, and 10D, and the wavelength-tunable multiline solid-state laser system 10F described with reference to FIG. 12 may be employed in place of the wavelength-tunable multiline solid-state laser system 10B.

Furthermore, an exposure apparatus may be used in place of the processing apparatus 4. Exposure apparatuses fall within the concept of processing apparatuses. The exposure apparatus uses a photosensitive substrate, such as a semiconductor wafer onto which photoresist has been applied, as the radiation receiving object 90. After the device pattern is transferred onto the semiconductor wafer by the exposure apparatus, a semiconductor device can be manufactured by carrying out a plurality of steps. The semiconductor device is an example of the “electronic device” in the present disclosure.

### 6. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser apparatus comprising:
a plurality of semiconductor lasers;
a plurality of optical switches disposed respectively in optical paths of the plurality of respective semiconductor lasers;
a wavelength conversion system configured to convert pulsed beams outputted from the plurality of optical switches in terms of wavelength to generate wavelength-converted beams;
an ArF excimer laser amplifier configured to amplify the wavelength-converted beams outputted from the wavelength conversion system; and
a controller configured to control operations of the plurality of semiconductor lasers and the plurality of optical switches,
the plurality of semiconductor lasers each being configured to output a laser beam so produced that wavelengths of the wavelength-converted beams outputted from the wavelength conversion system are wavelengths at which the ArF excimer laser amplifier performs amplification,
the laser beams outputted from the plurality of semiconductor lasers having wavelengths different from each other, and
the plurality of semiconductor lasers being configured to output the laser beams so produced that the wavelengths of the wavelength-converted beams differ from an optical absorption line of oxygen.

2. The laser apparatus according to claim 1,
wherein the plurality of semiconductor lasers are each configured to output the laser beam based on continuous wave oscillation, and
the plurality of optical switches are configured to convert the laser beams outputted from the plurality of semiconductor lasers into pulses at timings specified by the controller and output the pulsed beams.

3. The laser apparatus according to claim 2,
wherein the plurality of optical switches are each configured to perform the pulse conversion by performing the operation including controlling the beam passage timing and amplifying the beam.

4. The laser apparatus according to claim 1,
wherein the plurality of optical switches are each a semiconductor optical amplifier.

5. The laser apparatus according to claim 1,
wherein the plurality of semiconductor lasers are each a distributed feedback semiconductor laser, and
the controller is configured to specify an oscillation wavelength at which each of the plurality of semiconductor lasers operates.

6. The laser apparatus according to claim 1,
wherein the absorption line is present between at least any two of the wavelengths of the plurality of wavelength-converted beams generated by the wavelength conversion system.

7. The laser apparatus according to claim 1,
wherein the wavelength conversion system is configured to generate a fourth harmonic as each of the wavelength-converted beams.

8. The laser apparatus according to claim 1, further comprising
an optical amplifier disposed in an optical path between the wavelength conversion system and the plurality of optical switches.

9. The laser apparatus according to claim 8,
wherein the optical amplifier is a titanium-sapphire amplifier using a titanium-sapphire crystal.

10. The laser apparatus according to claim 8,
wherein the optical amplifier is a fiber amplifier using an optical fiber doped with an impurity.

11. The laser apparatus according to claim 1,
wherein the wavelength conversion system is configured to generate a second harmonic as each of the wavelength-converted beams.

12. The laser apparatus according to claim 1,
wherein a plurality of the wavelength conversion systems are arranged in series along an optical path.

13. The laser apparatus according to claim 12,
wherein a multiline pulsed laser beam generated by the wavelength conversion performed by the wavelength conversion systems and having a plurality of wavelengths is inputted to the ArF excimer laser amplifier, and
a difference between maximum and minimum wavelengths of peak wavelengths at multiple lines of the multiline pulsed laser beam is greater than 200 pm.

14. The laser apparatus according to claim 13,
wherein the difference between the maximum and minimum wavelengths of the peak wavelengths at the multiple lines of the multiline pulsed laser beam is smaller than or equal to 450 pm.

15. The laser apparatus according to claim 1, further comprising:
a first solid-state laser apparatus; and
a second solid-state laser apparatus,
wherein a first pulsed laser beam outputted from the first solid-state laser apparatus and a second pulsed laser beam outputted from the second solid-state laser apparatus enter the wavelength conversion system, and
at least one of the first solid-state laser apparatus and the second solid-state laser apparatus includes the plurality of semiconductor lasers and the plurality of optical switches.

16. The laser apparatus according to claim 15,
wherein the first solid-state laser apparatus includes
a first semiconductor laser,
a first optical switch disposed in an optical path of the first semiconductor laser,
a first optical amplifier configured to amplify a first pulsed beam outputted from the first optical switch, and
a first wavelength conversion system configured to convert in terms of wavelength a first amplified beam outputted from the first optical amplifier and output a first wavelength-converted beam,
the second solid-state laser apparatus includes
a plurality of second semiconductor lasers that are the plurality of semiconductor lasers,
a plurality of second optical switches that are the plurality of optical switches, and
a second optical amplifier configured to amplify second pulsed beams that are the pulsed beams outputted from the plurality of optical switches, and
a second wavelength conversion system that is the wavelength conversion system is configured to receive the first wavelength-converted beam outputted from the first wavelength conversion system and a second amplified beam outputted from the second optical amplifier and output the wavelength-converted beam having a sum frequency produced from the first wavelength-converted beam and the second amplified beam.

17. The laser apparatus according to claim 16,
wherein the first optical amplifier includes an Yb fiber amplifier using an optical fiber doped with Yb, and
the second optical amplifier includes an Er fiber amplifier using an optical fiber doped with Er.

18. The laser apparatus according to claim 16,
wherein a plurality of the wavelength conversion systems are arranged in series along an optical path.

19. A laser processing system comprising:
the laser apparatus according to claim 1; and
a processing apparatus configured to radiate an excimer laser beam outputted from the laser apparatus onto a radiation receiving object,
the processing apparatus including
a table on which the radiation receiving object is placed, and
a radiation optical system configured to guide the excimer laser beam outputted from the laser apparatus to the radiation receiving object on the table, and
the radiation optical system including
an optical path difference prism configured to lower coherence of the excimer laser beam outputted from the laser apparatus,
a mask configured to define an exposure pattern applied to the radiation receiving object,
a beam homogenizer disposed in an optical path between the optical path difference prism and the mask, and
a transfer optical system configured to transfer an image of the mask illuminated via the beam homogenizer onto a surface of the radiation receiving object.

20. A method for manufacturing an electronic device, the method using
a plurality of semiconductor lasers,
a plurality of optical switches disposed respectively in optical paths of the plurality of respective semiconductor lasers,
a wavelength conversion system configured to convert pulsed beams outputted from the plurality of optical switches in terms of wavelength to generate wavelength-converted beams,
an ArF excimer laser amplifier configured to amplify the wavelength-converted beams outputted from the wavelength conversion system, and
a controller configured to control operations of the plurality of semiconductor lasers and the plurality of optical switches,
the plurality of semiconductor lasers each being configured to output a laser beam so produced that wavelengths of the wavelength-converted beams outputted from the wavelength conversion system are wavelengths at which the ArF excimer laser amplifier performs amplification,
the laser beams outputted from the plurality of semiconductor lasers having wavelengths different from each other,
the plurality of semiconductor lasers being configured to generate excimer laser beams by using laser apparatuses configured to output the laser beams so produced that the wavelengths of the wavelength-converted beams generated by the wavelength conversion differ from an optical absorption line of oxygen, and
the method comprising outputting the excimer laser beam to a processing apparatus and irradiating a radiation receiving object with the excimer laser beam in the processing apparatus to manufacture an electronic device.
